(19) United States
(12) Patent Application Publication
(10) Pub. No.: US 2008/0239597 A1
(43) Pub. Date: Oct. 2, 2008

(54) Peak Voltage Protection Circuit and Method

(75) Inventors: Adrianus Van Bezooijen, Nijmegen (NL); Ronald Koster, Nijmegen (NL); Rob Mathijs Heeres, Nijmegen (NL); Dmitry Paviovich Prikhodko, Wijchen (NL); Bart Balm, Nijmegen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/575,727

(22) PCT Filed: Sep. 14, 2005
(86) PCT No.: PCT/IB2005/053013

§ 371 Date: Feb. 4, 2008

(30) Foreign Application Priority Data
Sep. 21, 2004 (EP) 04104569.1

(51) Int. Cl. H02H 3/20; H02H 3/24; H03F 1/52

(52) U.S. Cl. 361/56; 361/90

(57) ABSTRACT

A peak voltage protection circuit for protecting an associated High Voltage NPN transistor (T3) against breakdown, the protection circuit comprising a Low Voltage NPN element (T15) for sensing a sensor voltage related to a base-collector voltage of the associated High Voltage NPN transistor (T3). The circuit further comprises an activation circuit for limiting the base-collector voltage of the associated High Voltage NPN transistor (T3) upon triggering. The Low Voltage NPN element (15) is coupled to the activation circuit for triggering it upon the sensor voltage exceeding a breakdown voltage of the Low Voltage NPN transistor (T15).

The invention relates to the field of protection circuits and methods of peak voltage protection of transistors.

An important specification of a cellular phone Radio Frequency (RF) Power Amplifier (PA) is its ruggedness. Even under worst case conditions the PA shall not breakdown. Under antenna mismatch conditions and maximum output power of a PA large collector peak voltages occur that may exceed a breakdown voltage (BV) of the power transistor. A GSM PA has to survive a VSWR of 10:1, all phases, and Vbat=4.7V and thus has to be sufficiently rugged.

In bipolar IC-technology collector-base BV and transition frequency fT are strongly related, i.e. a product of BV of fi is approximately constant. Thus, a compromise between ruggedness and speed must be chosen. A trade-off is made by choosing an appropriate epi-thickness and collector dope profile. Bipolar IC-technologies optimised for GSM PAs are tuned for relatively high BVs and consequently have moderate fT. This reduces their possible gain and therefore the power added efficiency of the PA.

In Silicon technology epi-thickness and collector doping profiles are tuned for achieving an optimum trade-off between speed and ruggedness. Recent literature describing these trade-offs for a SiGe process are found in “Current Status and Future Trends of SiGe BiCMOS Technology”, IEEE Transactions on Electron Devices, Vol. 48, No 11, November 2001.

In low frequency high power switch applications it is common to protect the switching transistor with zeners, diodes etc. often referred to as “snubbers”. They limit the maximum peak voltage over the switching device and thus secure its ruggedness.

The data sheet of the BUK1M200-50 DLD “Quad channel TOPFET” mentions various types of integrated protections.

For Electro Static Discharge (ESD) protection of integrated circuits many different methods are know. Diodes and crowbars are most commonly used. Examples of literature describing protection against ESD pulses are “Diode Network Used as ESD Protection in RF Applications”, Proceedings EOS/ESD Symposium, 2001, pp. 337-345, and “New ESD protection schemes for BiCMOS processes with application to cellular radio designs”, International Symposium on Circuits and Systems 1992, Proceedings Vol. 6, 3-6 May 1992.

U.S. Pat. No. 6,525,611 B1A describes a method to limit maximum collector peak voltages. A peak detector is used to monitor the collector voltage. When it trips a certain level the PA biasing current and thus the output power is reduced. This patent mentions the potential power amplifier performance improvement that can be obtained because of the reduced breakdown voltage requirement on SiGe technology.

Patent application WO 03/034586 A1 discloses an alternative control loop as a method to prevent excessive collector peak voltages.

U.S. Pat. No. 5,977,823 describes an RF amplifier based on an RF transistor. Linearity of the RF amplifier is improved using a clipping circuit. In one embodiment of this clipping circuit demands to a low production spread are relaxed by utilising a difference in breakdown voltage of the RF and of another transistor with an inherently lower breakdown voltage than the RF transistor.

It may be seen as an object of the present invention to provide a protection circuit for and a method of protecting a transistor against peak voltage breakdown providing a precise protection voltage threshold that is independent on production spread. In addition, the circuit and method must be fast enough for protecting RF transistors.

According to a first aspect of the invention, this object is complied with by providing a peak voltage protection circuit adapted to protect an associated High Voltage NPN transistor against breakdown, the protection circuit comprising:

a Low Voltage NPN element connected so as to sense a sensor voltage related to a base-collector voltage of the associated High Voltage NPN transistor, and

an activation circuit adapted to limit the base-collector voltage of the associated High Voltage NPN transistor upon triggering, wherein the Low Voltage NPN element is connected to the activation circuit so as to trig it upon the sensor voltage exceeding a breakdown voltage of the Low Voltage NPN transistor.

In modern Si and SiGe processes a Selective Implant in the Collector (SIC) is used to optimise, in combination with the epi-thickness, the breakdown voltage and fT. Blocking this SIC results in a transistor with higher breakdown voltage compared to those with SIC. A transistor with SIC blocking is denoted a High Voltage NPN (HV-NPN) transistor. An element or transistor without SIC blocking is denoted a Low Voltage NPN (LV-NPN) element or transistor.

According to the first aspect an LV-NPN element (a collector-base junction) is used to sense a voltage indicative of the breakdown critical base-collector voltage of the HV-NPN transistor that may be e.g. a RF transistor in an RF power amplifier (PA) that needs protection against breakdown. Breakdown (non-destructive) of the LV-NPN element is then used to define a threshold voltage where an activator circuit is triggered, the activator circuit serving to limit or reduce base-collector voltage of the HV-NPN transistor—either directly or indirectly. Thus, the LV-NPN breakdown voltage is used as threshold value. Since breakdown voltage of the LV-NPN is inherently lower than breakdown voltage of the HV-NPN, the use of the LV-NPN breakdown to activate protection ensures that protection is activated at a voltage lower than breakdown voltage of the HV-NPN transistor to be protected. The breakdown voltage ratio may be e.g. 1.5. IC technology allows higher ratios, such as 3 or more, but such high ratio may be considered less practical.

In other words, the protection circuit according to the first aspect makes use of the inherent difference in breakdown voltage between the transistors with different collector-base doping profiles. As a result the safety margin between detection threshold level and actual breakdown voltage of the RF-device is well defined over temperature, process spread, etc.

The absolute values of breakdown voltages of the HV-NPN transistor (BV_{HV}) and the LV-NPN (BV_{LV}) element may vary due to different operation conditions and production spread, but still it is inherent that BV_{LV} will be lower than BV_{HV} and as such BV_{LV} is convenient to use as voltage threshold with respect to protection of a HV-NPN transistor. Using BV_{LV} as basis for protection voltage threshold it is ensured that the protection threshold is lower than the destructive BV_{LV} of the HV-NPN transistor to be protected and therefore a small safety margin can be used. If an absolute protection voltage threshold is used, it is necessary to introduce a large safety margin taking into account worst case conditions in order to guarantee that a potential breakdown will always be detected before BV_{HV} for the HV-NPN is actually exceeded. Consequently, a lower voltage threshold must be chosen, hereby introducing an unnecessary limit of operation area of the HV-NPN. Alternatively, a HV-NPN transistor must be chosen to have a higher breakdown voltage which will then limit the possible fT of the transistor.

A safety margin given by the difference in breakdown voltages BV_{HV} and BV_{LV} is accurate because spreads in the breakdown voltages BV_{HV} and BV_{LV} will occur in the same direction and in a similar amount because they are similarly correlated to process spreads.

The LV-NPN element may be connected so as to directly sense the base-collector voltage of the HV-NPN transistor. With this configuration a trigger threshold voltage equal to the breakdown voltage of the LV-NPN element is obtained. However, it may alternatively be connected so as to sense a voltage indirectly related to the base-collector voltage of the HV-NPN transistor, such as by using further components, thus obtaining that the activation circuit is triggered at a base-collector voltage of the HV-NPN transistor different from the breakdown voltage of the LV-NPN element.

The activation circuit may be adapted to limit the base-collector voltage of the associated HV-NPN transistor by reducing a gain of the HV-NPN transistor.

In preferred embodiments a LV-NPN element comprises a LV-NPN transistor connected as a reverse biased collector-base diode. The LV-NPN element may comprise an Electro Static Discharge (ESD) diode.

In some embodiments the activation circuit comprises a clamping transistor adapted to clamp the collector output of the HV-NPN transistor upon triggering. In other embodiments, the activation circuit comprises an attenuator adapted to attenuate an input signal to the HV-NPN transistor upon triggering. In still other embodiments, the activation circuit is adapted to reduce a DC biasing voltage of the HV-NPN transistor upon triggering, hereby reducing the base-collector voltage of the HV-NPN transistor. The activation circuit may also be adapted to reduce a gain and/or a DC biasing voltage of an amplifier stage preceding the HV-NPN transistor upon triggering, thus reducing an input signal amplitude to the HV-NPN transistor and thereby reducing its base-collector voltage.

In yet other embodiments the activation circuit comprises the associated HV-NPN transistor, and wherein the LV-NPN element is adapted to directly reduce the base-collector voltage of the HV-NPN transistor upon the sensor voltage exceeding the breakdown voltage of the LV-NPN element.

The LV-NPN element may be connected to sense a base-collector voltage of the associated HV-NPN transistor.

The LV-NPN element may exhibit a breakdown voltage differing from a base-collector breakdown voltage of the associated HV-NPN transistor by a factor of approximately 1.5.

A second aspect of the present invention provides a method of peak voltage protecting a HV-NPN transistor comprising the step of utilising a difference in breakdown voltage between the HV-NPN transistor and a LV-NPN element to protect the HV-NPN transistor against a base-collector breakdown.

Preferably, the method comprises the step of sensing a sensor voltage related to a base-collector voltage of the HV-NPN transistor using the LV-NPN element, and reducing the base-collector voltage of the HV-NPN transistor upon the sensor voltage exceeding the breakdown voltage of the LV-NPN element.

The step of reducing the base-collector voltage of the HV-NPN transistor may comprise reducing a voltage gain of the HV-NPN transistor.

The LV-NPN element preferably comprises a LV-NPN transistor in a diode configuration.

A third aspect of the invention provides an RF power amplifier comprising:

a High Voltage power transistor,

a protection circuit according to the first aspect.

A fourth aspect of the invention provides an electronic chip comprising an RF power amplifier according to the third aspect.

A fifth aspect of the invention provides an RF device comprising an RF power amplifier according to the third aspect. The RF device may be selected from the group consisting of: mobile phones, laptop computers, Personal Digital Assistants (PDAs), PCMCIA cards.

It is appreciated, that a protection circuit according to the first aspect, a protecting method according to the second aspect or an RF power amplifier according to the third aspect may applied also within a wide range of other type of equipment. Non-exhaustive examples are: line drivers, such as optical line drivers, switched power supplies, power management units (PMUs).

In the following the invention is described in more details with reference to the accompanying figures of which

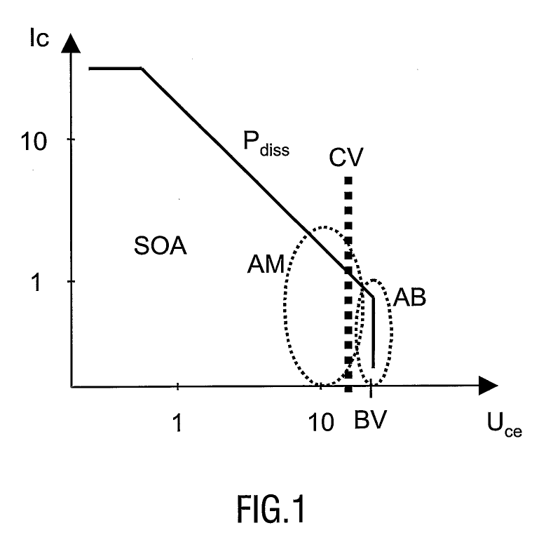

FIG. 1 shows a graph illustrating a safe operation area (SOA) of an RF power transistor,

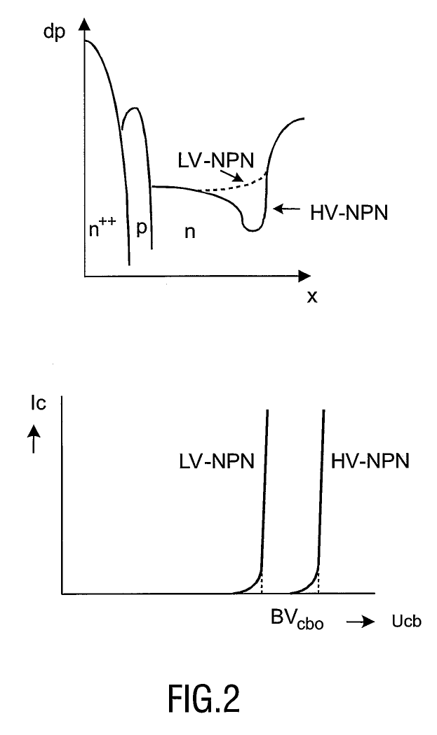

FIG. 2 illustrates differences between LV-NPN transistors and HV-NPN transistors. Upper part shows doping profiles for the two transistors types, while lower part illustrates their different collector-base breakdown voltages,

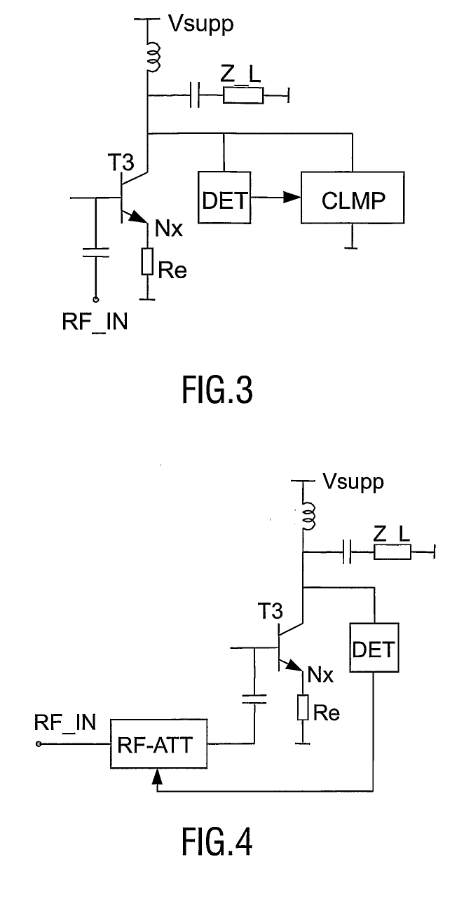

FIG. 3 illustrates a first protection principle based on a clamp circuit,

FIG. 4 illustrates a second protection principle based on input attenuation,

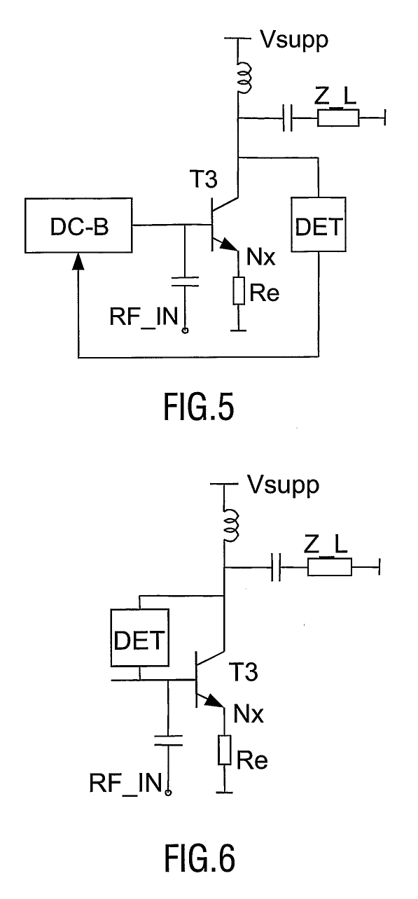

FIG. 5 illustrates a third protection principle based on DC-biasing reduction,

FIG. 6 illustrates a fourth protection principle based on triggering of the transistor to be protected,

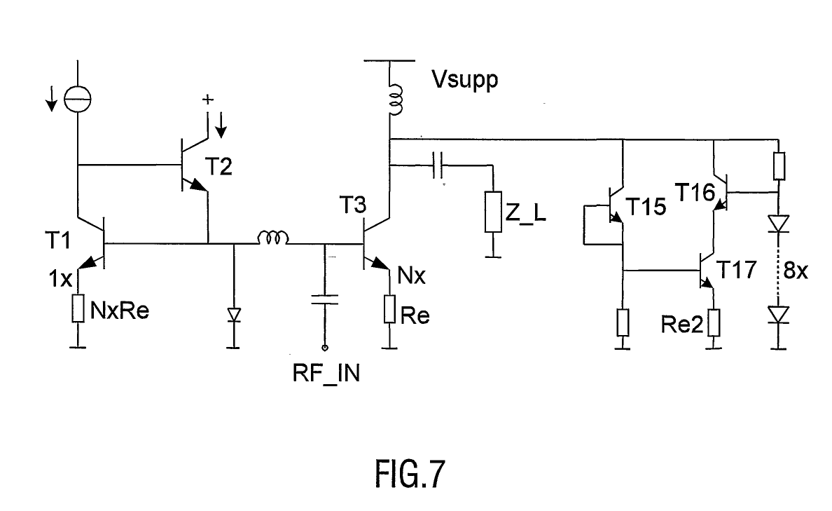

FIG. 7 illustrates a preferred implementation of the first protection principle,

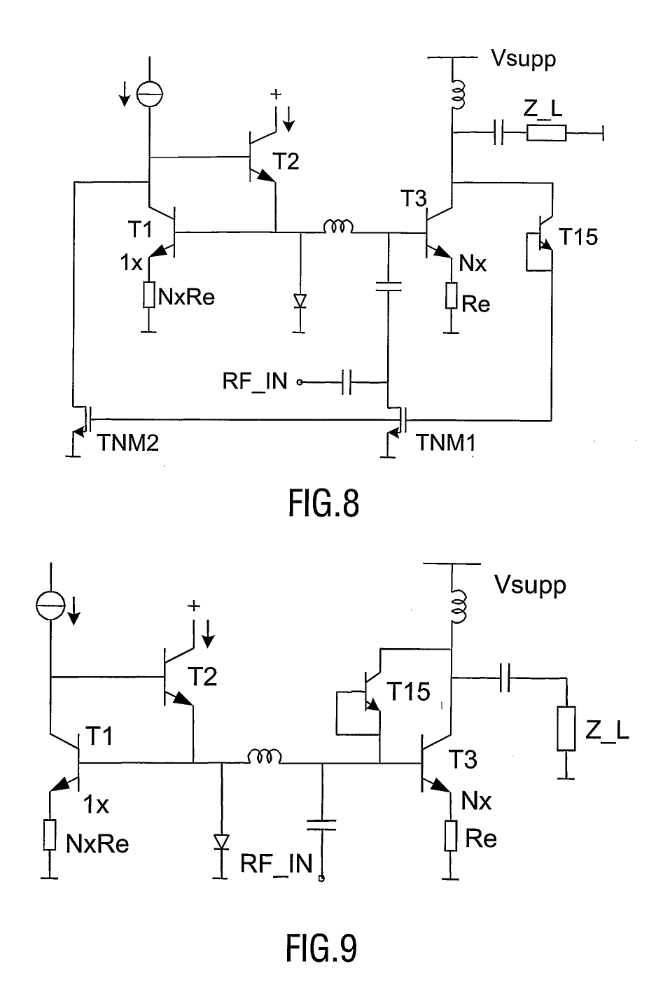

FIG. 8 illustrates a preferred implementation of the second and third protection principles, and

FIG. 9 illustrates a preferred implementation of the fourth protection principle.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

FIG. 1 shows a typical safe operating area (SOA) of a power transistor, i.e. for collector current I_{c} versus collector-emitter voltage U_{ce}. For high and medium collector currents and voltages SOA is limited by the dissipated power indicated by the linear piece of the curve indicated by P_{diss}. However, for low collector currents the SOA is limited by a region of avalanche multiplication AM indicated by a dashed circle, where a breakdown can build up and go into a region of avalanche breakdown AB indicated by another dashed circle. In the avalanche breakdown region AB the transistor will reach its breakdown voltage BV of the collector-base junction. A typical position of a clamp voltage CV that can be used for detection threshold with respect to protection is indicated by the bold dashed straight line. If a fast protection is activated as the clamp voltage CV is exceeded, it is still possible to save the transistor from the destructive breakdown voltage BV.

FIG. 2, upper part, illustrates examples of doping profiles dp for a LV-NPN transistor (dashed curve) and a HV-NPN transistor (solid curve) as a function of position x. As seen, the LV-NPN and HV-NPN transistors have identical doping profiles except for n-doped collector layer, where the Selective Implant in the Collector (SIC) blocking of the HV-NPN transistor is clearly seen to distinguish it from the LV-NPN transistor.

FIG. 2, lower part, illustrates the resulting collector current I_{c} as a function of collector-base voltage U_{bc} for the two transistor types. As it is seen there is a difference in BV between the two transistor types, indicated by BV_{LV} and BV_{HV} respectively. BV_{LV} is inherently lower than BV_{HV}. Since this difference between BV_{LV} and BV_{HV} is due to structural differences defined by the different doping profiles, indicated in upper part of FIG. 2, the BV difference is well-defined with respect to production spread, temperature etc.

According to the invention this inherent difference in BV_{LV} and BV_{HV} is utilised to define a peak voltage detection threshold in a protection circuit. Non-destructive BV_{LV} of a LV-NPN transistor is used to define a maximum allowable peak collector voltage of the HV-NPN transistor and thus to define a protection threshold voltage. As this threshold voltage is exceeded, an activation circuit is triggered. The activation circuit then serves to reduce the collector voltage to a safe level so as to protect the HV-NPN transistor.

In the following, FIGS. 3-6, four different protection circuit principles are described. All four principles are based on protecting a HV-NPN power transistor T3 against breakdown due too high collector-base voltage peak. T3 is supplied by a supply voltage Vsupp, and it drives a load Z_L in response to on an input signal RF_IN. All protection circuits make use of a collector peak voltage detector DET based on a LV-NPN transistor, utilising its BV_{LV} to activate a circuit that limits an effective (voltage) gain of the HV-NPN transistor. Since the LV-NPN is connected so that it is not heavily loaded, reaching the BV_{LV} will be non-destructive for the LV-NPN transistor. Preferably, the LV-NPN transistor used as voltage detector is with its base-emitter short-circuited. By adding one or more base-emitter-diodes in series with the LV-NPN the effective threshold detection level can be adjusted in steps of Ube.

FIG. 3 shows the first protection principle where the detector DET based on a LV-NPN detector element, is connected to detect a collector voltage of T3. As the peak voltage detector DET detects a collector voltage exceeding the BV_{LV} of the detector LV-NPN, the detector DET triggers a clamping circuit CLMP that in some way clamps the collector voltage of T3, so that the collector voltage of T3 is reduced. Since the collector of T3 is clamped at BV_{LV}, i.e. lower than its own breakdown voltage BV_{HV}, T3 is protected against breakdown.

FIG. 4 shows a second principle where the detector DET triggers an attenuator RF-ATT positioned at the input of T3. As the detector DET detects a collector voltage exceeding BV_{LV} it triggers the attenuator RF-ATT that attenuated the input signal RF_IN so as to reduce input to T3 and consequently reduce its collector voltage prior to reaching BV_{HV}.

FIG. 5 shows a third principle where a detector DET triggers a circuit DC-B serving to DC-bias T3. As the detector DET detects a collector voltage exceeding BV_{LV} it triggers the DC-biasing circuit DC-B that in response reduces DC bias of T3 and consequently reduces the collector voltage prior to reaching BV_{HV}.

FIG. 6 shows a fourth principle where a detector DET triggers T3 directly as the detector DET detects a collector voltage exceeding BV_{LV}. Hereby, T3 can be directly influenced so as to reduce its collector voltage and consequently it is protected against reaching BV_{HV}.

In the following three embodiments of the described protection principles will be described in connection with FIGS. 7, 8 and 9. In all three embodiments an RF PA based on a HV-NPN power transistor T3 is connected to drive a load Z_L in response to an input signal RF-IN. A supply voltage is Vsupp. Under extreme conditions (high battery voltage Vsupp, high load impedance Z_L, high output power) the collector peak voltage of T3 becomes large. T3 is DC biased by a DC biasing circuit based on transistors T1 and T2. In all three embodiments of FIGS. 7, 8 and 9, a peak voltage detector is implemented as a LV-NPN transistor T15 configured as a reverse biased collector-base diode. It may be implemented as an ESD diode having a structure optimised for good current handling capability and therefore it is compact.

FIG. 7 shows an implementation of an RF PA with a protection circuit according to the first principle described, i.e. based on a clamping circuit. A clamp circuit comprises HV-NPN transistors T16 and T17. When the peak collector voltage of T3 exceeds Ube_17+BV_T15+U_Re2, i.e. a detection voltage threshold, current flows through T15 which drives T17. T17 and its cascading transistor T16 conduct a large clamp current. Consequently, the collector voltage of T3 is being limited.

The detector LV-NPN transistor T15 is configured as a reverse biased junction that triggers the actual clamping transistor T17. Due to the current gain of T17 the required current handling capability of T15 is limited which allows using a relatively small device. T17 operates in a normal mode. Its power dissipation is limited by using a transistor T16 and thus to distribute the dissipated power over T17 and T16. Moreover, the use of the cascode prevents avalanche breakdown of T17. A stack of diodes is used to generate the base reference voltage of T16. The large number of diodes in this stack prevents any leakage current in the clamp even when the battery voltage is high. In the example shown in FIG. 7 a stack of 8 diodes are used in connection with a maximum supply voltage of 5 V.

The non-destructive breakdown of LV-NPN T15 and the HV-NPN T16, T17 are fast and thus can follow collector voltage variations of the RF transistor T3 well. The feed forward circuit concept used guarantees good stability. More than one clamp may be used in parallel to distribute the protection over the die area of the distributed PA. High power densities in T17 might cause thermal instability of T17. Similar to the thermal stability of the RF transistor T3, it can be improved by applying distributed (emitter) degeneration Re2.

FIG. 8 shows a protection circuit embodiment based on the described second or third protection principles. The detector LV-NPN T15 transistor is used to trigger an RF attenuator and/or bias circuit to limit the maximum collector voltage of the RF transistor T3. TNM1 serves to reduce DC biasing of T3 upon triggering, while TNM2 serves to attenuate the RF input signal of T3 upon triggering. In the circuit of FIG. 8 the maximum collector voltage of the RF transistor T3, i.e. detection threshold voltage, equals Uth_NM1/2+BV_T15.

FIG. 9 shows a protection circuit embodiment based on the fourth described protection principle, i.e. direct triggering of the PA transistor to be protected. In FIG. 9 shows a detector LV-NPN transistor T15 directly triggers the RF HV-NPN transistor T3 to limit the peak collector voltage of the RF transistor T3. The maximum collector voltage, i.e. the protection threshold voltage, equals Ube_T3+BV_T15+U_Re.

In the claims reference signs to the figures are included for clarity reasons only. These references to exemplary embodiments in the figures should not in any way be construed as limiting the scope of the claims.

It is remarked that the scope of protection of the invention is not restricted to the embodiments described herein. Neither is the scope of protection of the invention restricted by the reference numerals in the claims. The word ‘comprising’ does not exclude other parts than those mentioned in the claims. The word ‘a(n)’ preceding an element does not exclude a plurality of those elements. Means forming part of the invention may both be implemented in the form of dedicated hardware or in the form of a programmed purpose processor. The invention resides in each new feature or combination of features.

1. Peak voltage protection circuit for protecting an associated High Voltage NPN transistor against breakdown, the protection circuit comprising:
a Low Voltage NPN element for sensing a sensor voltage related to a base-collector voltage of the associated High Voltage NPN transistor, and
an activation circuit for limiting the base-collector voltage of the associated High Voltage NPN transistor upon triggering,
wherein the Low Voltage NPN element is coupled to the activation circuit for triggering it upon the sensor voltage exceeding a breakdown voltage of the Low Voltage NPN transistor.

2. Protection circuit according to claim 1, wherein the activation circuit is provided for limiting the base-collector voltage of the associated High Voltage NPN transistor by reducing a gain of the High Voltage NPN transistor.

3. Protection circuit according to claim 1, wherein the Low Voltage NPN elementally comprises a Low Voltage NPN transistor connected as a reverse biased collector-base diode.

4. Protection circuit according to claim 1, wherein the Low Voltage NPN element comprises an Electro Static Discharge diode.

5. Protection circuit according to claim 1, wherein the activation circuit comprises a clamping transistor for clamping the collector output of the High Voltage NPN transistor upon triggering.

6. Protection circuit according to claim 1, wherein the activation circuit comprises an attenuator (RF-ATT) for attenuating an input signal (RF-IN) to the High Voltage NPN transistor upon triggering.

7. Protection circuit according to claim 1, wherein the activation circuit (DC-B) is provided for reducing a DC biasing voltage of the High Voltage NPN transistor upon triggering.

8. Protection circuit according to claim 1, wherein the activation circuit (DC-B) is provided for reducing a DC biasing voltage of an amplifier stage preceding the High Voltage NPN transistor upon triggering.

9. Protection circuit according to claim 1, wherein the activation circuit (DC-B) is provided for reducing a gain of an amplifier stage preceding the High Voltage NPN transistor upon triggering.

10. Protection circuit according to claim 1, wherein the activation circuit comprises the associated High Voltage NPN transistor, and wherein the Low Voltage NPN element is provided for directly reducing the base-collector voltage of the High Voltage NPN transistor upon the sensor voltage exceeding the breakdown voltage of the .Low Voltage NPN element.

11. Protection circuit according to claim 1, wherein the Low Voltage NPN element is connected to sense a base-collector voltage of the associated High Voltage NPN transistor.

12. Method of peak voltage protecting a High Voltage NPN transistor comprising the step of
utilising a difference in breakdown voltage between the High Voltage NPN transistor and a Low Voltage NPN element to protect the High Voltage NPN transistor against a base-collector breakdown.

13. Method according to claim 12 further comprising the steps of
sensing a sensor voltage related to a base-collector voltage of the High Voltage NPN transistor using the Low Voltage NPN element,
reducing the base-collector voltage of the High Voltage NPN transistor upon the sensor voltage exceeding the breakdown voltage of the Low Voltage NPN element.

14. Method according to claim 13, wherein the step of reducing the base-collector voltage of the High Voltage NPN transistor comprises a step of reducing a voltage gain of the High Voltage NPN transistor.

15. Method according to claim 12, wherein the Low Voltage NPN element comprises a Low Voltage NPN transistor in a diode configuration.

16. RF power amplifier comprising a High Voltage power transistor and a protection circuit according to claim 1.

17. An electronic chip comprising an RF power amplifier according to claim 16.

18. RF device comprising an RF power amplifier according to 16.
